(19) United States
(12) Patent Application Publication
(10) Pub. No.: US 2007/0050871 A1
(43) Pub. Date: Mar. 1, 2007

(54) Scheme for spreading and facilitating remote e-services

(76) Inventor: Ashraf Kamal Salem Mashhour, Greater Cairo (EG)

Correspondence Address: Ashraf Kamal Salem Mashhour, 9(a) Amer St., Apt 12, Floor 5, Messaha, Dokki Giza/Greater Cairo, 12311, EG

(21) Appl. No.: 10/546,543

(22) PCT Filed: Nov. 15, 2003
(86) PCT No.: PCT/EG03/00007

§ 371 Date: Oct. 31, 2005

(30) Foreign Application Priority Data
Nov. 24, 2002 (EG) 200211/1268

(51) Int. Cl. H01L 23/495

(52) U.S. Cl. D14/383; 257/674; 902/37

(57) ABSTRACT

An Orchestrated “e-Services/e-Payment” Scheme that extends the e-Services currently available on Mobile Devices platform to Landline Handsets, integrates and combines: Various Shapes of Authentication/Authorization Tools (Smart SIM's used in Mobile Phones and Smart Cards used in ATM's); Various e-Access Terminals (Fixed-Phones, Personal Computers, Mobile Phones, Handheld Devices, . . . etc); Various Types of e-Services Applications (Internet, WAP and IVR without need for Personal Computers); Various e-Payment Instruments (Credit Cards, Prepaid Electronic Accounts, and Prepaid Cards without need for Credit or Bank Accounts). Also the Scheme avails Printing of “Payment Receipts” through various alternatives (including new printing services via ATM machines).

### TECHNICAL FIELD

The invention is related to the fields of Data Communications via means of mobile and fixed line telephones using the Electronic Service applications of Internet, WAP (Wireless Application Protocol) and IVR (Interactive Voice Response).

The invention is an innovative solution that introduces one orchestrated scheme of remote accessing of electronic services (e-Commerce, e-Government) and e-Payment that enjoy a good level of authentication of the remote user identity and as well enjoy a good level of personalized access control of remote users and a good level of protection of their processed transactions.

The presented invention provides means of accessing electronic services remotely (while at home or office) in a secured manner that complements the onsite secured accessing of electronic services (while at banks, commercial malls, shops . . . etc) using the POS (Point Of Sale) and ATM (Automatic Teller Machines).

### BACKGROUND ART

In the background art, the e-Services/e-Payment applications that enjoy a good level of end-user authentication/authorization functionalities are either:
Mobile Devices based applications, or
Desktop Personal Computer/Internet based applications, or
Fixed-Phones/Chip Card Reader applications.

In background art, the following points are noted in the Mobile Devices based applications:
The e-Services (e-Government and e-Commerce) and e-Payment solutions are available for Mobile Devices' users and can be processed via SMS, Internet and WAP (Wireless Application Protocol) applications.
Some of these Mobile based “e-Services/e-Payment” solutions enjoy a good level of authentication/authorization techniques, where these solutions:
   Depend on using the SIM Cards in association with the SIM based applications that are installed within the central management systems of the Telecom Operator managing mobile phone networks.
   Utilize the inside plant systems of the Mobile Telecom Operators, that are normally used to manage the mobile phone services, after introducing to it the necessary development and re-engineering activities to make it suitable for managing and controlling the “e-Services and e-Payment” transactions.
   Include authentication/authorization processes of end-users requesting to access “e-Services/e-Payment” applications and handle their transactions, where these authentication/authorization processes utilize various security and protection techniques/tools, such as:
      Public Key and Private Key Infrastructure (PKI).
      Electronic Signature.
      Data Encryption/Decryption.
      . . . Etc).
End-user has to have a Handheld Device or a Laptop (or Pocket) Personal Computer equipped with wireless communication facilities (such as GSM or GPRS).
Effecting e-Payments via most of these applications necessitate that end-user has a Credit Card
Some of the Mobile based applications permit the use of the prepaid cards.
Some of the Mobile based applications accommodate for the prepaid (interim) account techniques, that reduce payment risks and cater for the legal requirements that may be entailed by some financial institutions.
The handling of the e-Services/e-Payment transactions via SMS, WAP or Internet (using Laptop or Pocket PC's) applications require end-user to have technical competence/PC literacy.
The handling of the e-Services/e-Payment transactions via IVR (Interactive Voice Response) is not as convenient as using the IVR via fixed-line telephone sets.

In background art, the following points are noted in the Desktop Personal Computer/Internet based applications:
It is possible to authenticate the end-user identity using Smart Cards applications, in which case the PC has to be equipped with a USB port (Universal Serial Bus) or with an RS232 interface (parallel or serial ports) to connect the Smart Card reader to the Desktop PC.
In case of using Smart Cards/Smart Cards Readers, the end-user has to install special software programs that are necessary to complement the e-Services/e-Payment central systems in handling of the authentication/authorization processes, where installing such a special software on the end-user PC side has the following limitations:
   The first limitation is the complexity added to the end-user responsibilities to be able to handle e-Services and e-Payments.
   The second limitation is the security weaknesses that associate the installation of authentication/authorization software on the remote end PC, outside the control of centralized systems governing the e-Services/e-Payments transactions.
Some of the Desktop PC applications realize the security of the e-Payments via Credit Cards through the use of “Authorization Codes” (without using Smart Cards as a physical authentication token), where the end-user (Consumer) effects e-Payments via Credit Cards in association with the use of “Authorization Codes” that are stored on an Agent's host (interim/prepaid account) in addition to the data of the Vendors accepting such “Authorization Codes”. The limitations of such a solution are mainly represented in the complexity of the setup and the low appreciation of the introduced security perceived by the Credit Card holder consumers.
In the solutions that are based on the Internet/PC applications, the end-user has to have a desktop personal computer equipped with a Fax/Modem device or card, the thing that hinders the spreading of the electronic services usage, specially within developing country environments, due to the following reasons:
   Limited number of installed PCs within a greater number of households, and relatively smaller number of households can afford purchase of a PC.
   The lack of skills needed to use the PCs and internet applications within a majority of individuals specially within developing countries limits the number of individuals who are capable of using the Internet applications compared to the number of individuals who can conveniently use the fixed-line IVR services.
Effecting e-Payments necessitate that end-user has a Credit Card, this again hinders the spreading of the electronic services usage, specially in the developing countries where the incomes are low and people who can afford to have bank accounts or credit cards are limited.

In background art, the following points are noted in the Fixed-Phones/Chip Card Reader applications:
There is an introduced solution that adds a “Chip Card Reader” to the Landline Handset to transform it to a POS-Alike apparatus.
The end-user, requesting to remotely access his/her bank account, will be authenticated upon dialing the “Tele-Banking” central exchange systems, where system will prompt the end-user to insert his/her “Chip Card” into the “Chip Card Reader”.
In the authentication process, the “Chip Card Reader” takes over the landline and forwards the authentication data stored on the “Chip Card” to an authentication mechanism installed at the central exchange of the dialed system and upon completion of the authentication process the “Chip Card Reader” surrenders the landline and the end-user becomes able to remotely perform requested transactions.
To effect remote e-Payments, the “Chip Card” is used as an electronic purse, where the end-user re-fills an amount of money from his/her bank account into the electronic purse through dialing the “Tel-Banking System”, and can afterwards dial the “Service Provider System” to upload the amount of money from the electronic purse, where in the later case, both of the authentication and money transfer processes are performed when the “Chip Card Reader” takes over the landline.
The previously available “Chip Card Reader” solution is primitive, and is inconvenient to end-users, as it requires multiple dialing and authentication processes to be done to perform a simple operation of remote transfer of a monetary amount from the end-user bank account to the service provider account.
The previously available “Chip Card Reader” solution, does not cope with the authentication/authorization processes required when the end-user requires to access the e-Services/e-Payment through internet websites using a Desktop Personal Computer hooked to the landline.
The previously available “Chip Card Reader” does not read the SIM cards used in Mobile Phones/Devices and consequently does not enable the providers nor the end-users of benefiting from the e-Services/e-Payment systems and solutions that are currently available for the Mobile Platform.

In addition, and considering the various solutions that are available in the background art (Mobile Devices, Desktop PC/Internet and/or Fixed Phone/Chip Card Reader), none of these inventions had introduced one unified solution that embodies in one orchestrated scheme and caters for the following items:
Interchangeable and integrated use of all various types of SIM and Smart Cards that are used in Mobile Phones, ATM/POS machines, Card Readers connected to Personal Computers and Card Readers connected to (or integrated inside) landline handsets.
Integrated and complementary use of the various types of e-Payment embodiments (prepaid cards, prepaid accounts, credit cards, debit cards, . . . etc).
Applicability and compatibility with all various e-Services Access tools, apparatus and terminals (Mobile Phones, Handheld Devices, Personal Computers connected to landlines as well as Fixed-Line Telephone Handsets without the need to use any Personal Computers).
Availability of various types of e-Services/e-Payment applications (IVR, Internet and WAP) through one unified and orchestrated e-Services/e-Payment Scheme.

### DISCLOSURE OF THE INVENTION

The objective of this invention is to achieve the following:
Extend the use of the e-Services/e-Payment tools and applications, that utilize SIM Cards in authenticating remote end-users, and that currently exist on the Mobile Phones platform to the Fixed-Phones platform (for the objective of the presented invention the central systems that will be re-engineered/developed to manage and control the e-Services/e-Payment applications, can be the inside plant central systems of a Mobile Phones Telecom Operator, or also can be the inside plant Intelligent Network Systems of a Fixed Phones Telecom Operator that are normally used to manage the fixed phone subscribers' services).
Introduce a scheme that helps in closing the “Digital Divide” by enabling the poor and lowly educated personnel round the whole world (and specially within the developing countries) of easily and confidently using the e-Services and effecting e-Payments remotely, where:
   The end-users will be able to interact with the e-Services transactions via IVR (Interactive Voice Response) applications without the need for any Personal Computers, while enjoying the values of authentication/authorization controls, through the use of a handy card reader tool that is easily connectable to fixed line telephone sets via normal RJ type connectivity.
   The introduced scheme will enable the end-users of effecting e-Payments via prepaid cards/electronic banking scheme without the need of having credit.
Introduce a scheme that also provides values to the end-users who are rich, professional and highly educated, where it introduces new service features that can be added to the use of credit cards (such as Visa, Masters, . . . etc) that would eliminate the possibility of unjustified use of credit cards in effecting e-Payments over the internet.
Introduce a scheme that avails for all types of users (whether they are poor or rich, highly or lowly educated, using IVR or Internet) one unified authentication/authorization scheme that links and integrates the following various e-Services and e-Payment tools and technology solutions and avail it through One Orchestrated Scheme:
   Various types of SIM and Smart Cards that are used in Mobile Phones, ATM/POS machines, Card Readers connected to Personal Computers and card readers connected to (or integrated inside) landline handsets.
   Various types of e-Payment mechanisms (prepaid cards, prepaid accounts, credit cards, debit cards, . . . etc).
   Various e-Services Access tools, apparatus and terminals (Mobile Phones, Handheld Devices, Personal Computers connected to Fixed-Line Phones as well as Fixed-Line Phones without the need to use any Personal Computers).
   Various types of e-Services/e-Payment applications (IVR, Internet and WAP).
Provide the e-Services/e-Payment end-users with Printed Payment Receipts through various alternatives (end-user local printing facilities, ATM machines printing services and/or e-Services Provider Printing Facilities and delivering printed receipts to end-user via mailing courier).

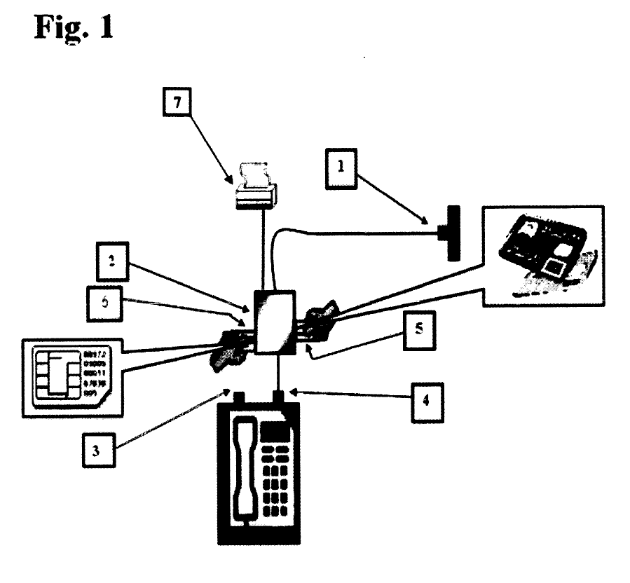

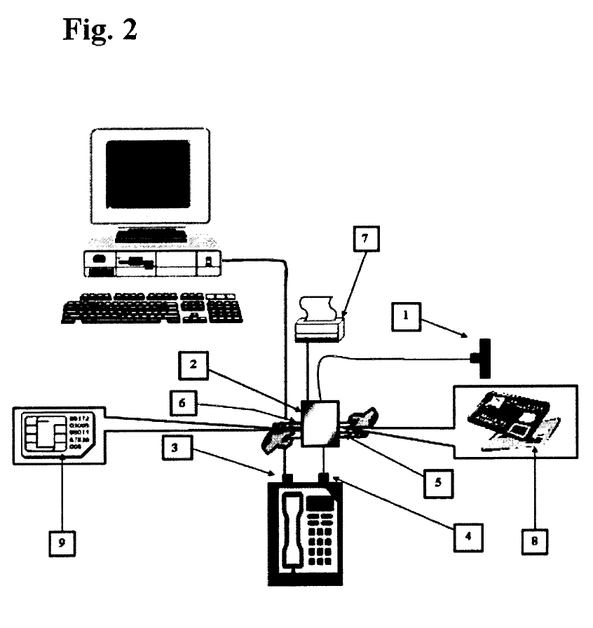

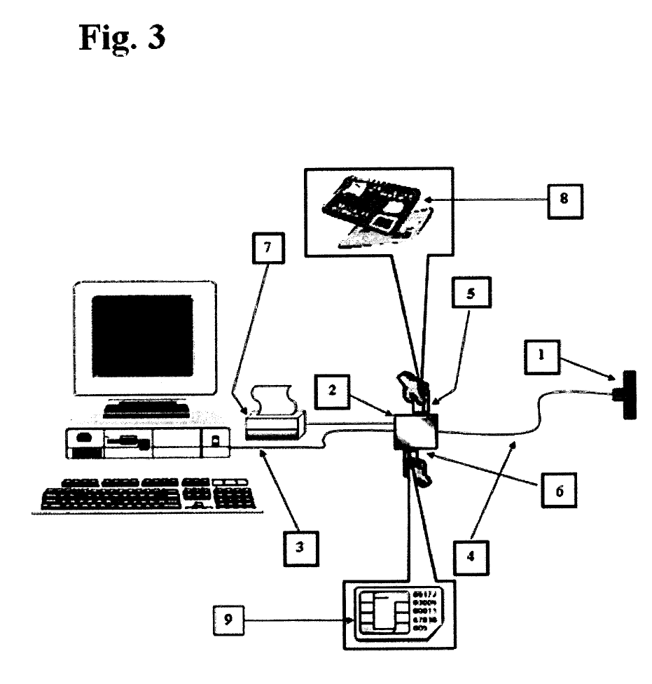

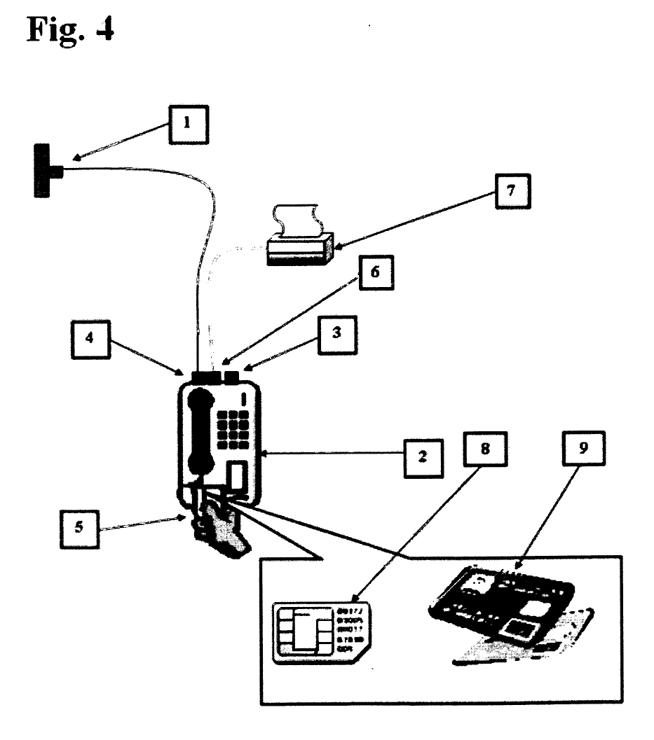

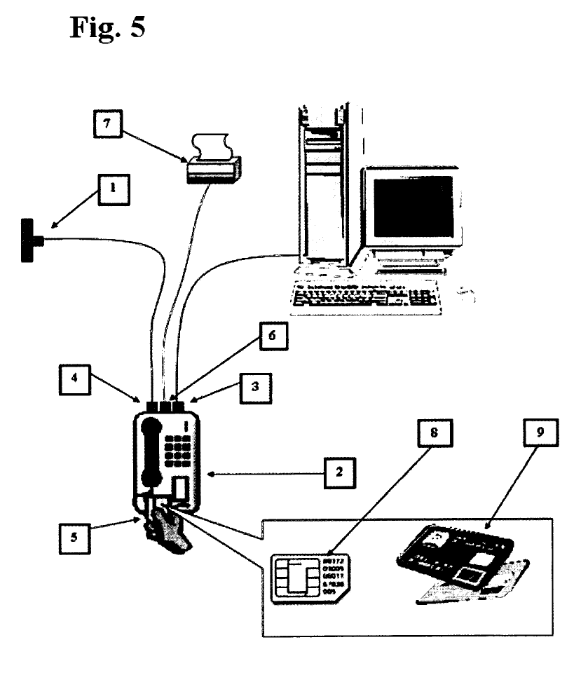

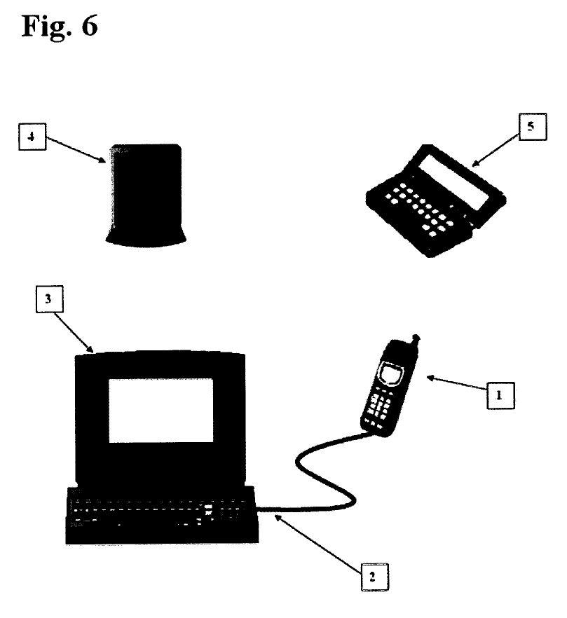

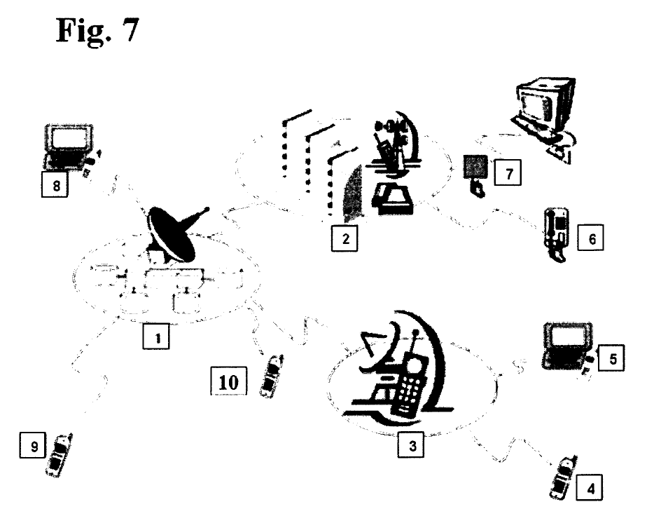

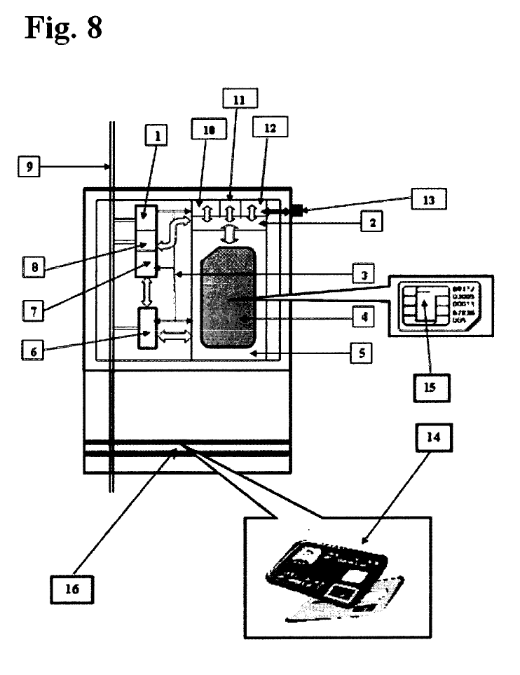

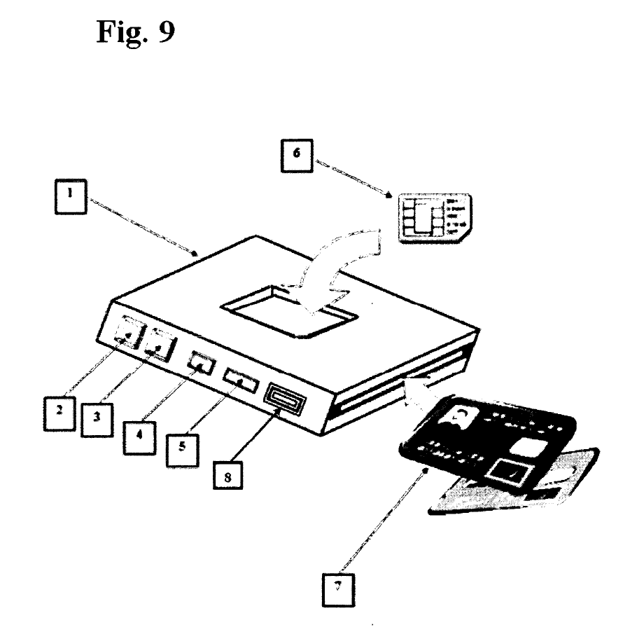

To achieve the above mentioned objectives, the presented invention introduces the following:
(1) Two versions of Smart Cards to be issued for each e-Services Subscriber, where:
   Version #1, a new e-Services SIM Card (which is a modified smart version of the SIM cards currently used in mobile phones), where the e-Services end-user can use this new SIM card to perform the following:
      The traditional mobile phone services
      Acquire e-Services from e-Service Providers and perform the respective e-Service and e-Payment transactions through the e-Services applications and authentication/authorization processes, similar to what is currently available for Mobile Phones/Wireless Devices.
      In addition the end-user can use the very same SIM Card in association with the Fixed-Line Phones through the use of the new SIM/Smart Cards Reader described in the claim item #3 mentioned below in this report, where the end-user will be able to acquire e-Services from e-Service Providers and perform the respective e-Service transactions through the e-Services IVR applications (without the need for Personal Computers), or through the Internet applications (using Personal Computers), in association with the authentication/authorization processes in place.
   Version #2, is a new e-Services Smart Card (a modified smart version of the cards normally used in Automatic Teller Machines “ATMs”), where the e-Services end-user can use this new Smart Card to perform the following:
      The traditional Automatic Teller Machines “ATMs” services.
      In addition the end-user will be able to use the same Smart Card in association with the novel SIM/Smart Cards Reader that is also introduced through this invention (and described in the claim item #3 mentioned below in this report), where the end-user will be able to acquire e-Services from e-Service Providers and perform the respective e-Service and e-Payment transactions via Fixed-Line Phones, while enjoying the values of the authentication/authorization processes in place via the very same e-Services applications and authentication/authorization processes currently available for Mobile Phones/Wireless Devices. Where, the e-Service/e-Payment applications will be available through:
         IVR applications (without the need for Personal Computers), or
         Internet applications (using Personal Computers connected to Fixed-Line Phones).
   The two versions of the e-Services Cards (SIM and Smart Cards) will be issued by the entity/organization responsible on a country level for providing the Public Key/Private Key Infrastructure needed for the e-Services/e-Payments. This organization shall allow and coordinate with:
      The normal mobile operators to add the cellular telephone line data on the same e-services SIM Card, so that the end-user can use the same new SIM Card for e-services in addition to the cellular telephone line voice calls, and other mobile phone services provided by the mobile operator.
      Banks and Financial Services Institutions (such as Visa, Master Card, American Express . . . etc) to add their end-user data on the same e-Services SIM and normal size Smart Cards, so that the end-user can use the same new SIM or normal size Smart Cards for the e-Services provided through the invented scheme in addition to the normal banking, financial and e-Payment services that are (and will be) provided by these banks and financial institutions, where the end-user will be enjoying the same level of authentication/protection privileges provided by the invented scheme for the landline users accessing the e-Services via IVR or Internet applications.
   The presented invention introduces a new SIM/Smart Card Reader that is directly connected to the fixed line telephones using normal telephone line RJ type connections and without the need for special interfaces, connectors or adapters (FIGS. 1, 2 and 3). Where, the newly invented SIM/Smart Card Reader includes the following basic and optional features that aim to enhance the effectiveness and efficiency of its use in the e-Services applications:
      The tools and functions of the newly invented SIM/Smart Card Reader depend on BIOS (Basic Input Output System) and Micro Codes that can be updated and upgraded through the use of specialized PC (Personal Computer) programs. To perform such an upgrade, the SIM/Smart Card reader connects to the PC through USB interface port (9 figure item 8).
      The electronic and logic circuitry of the SIM/Smart Card Reader include (as standard features) TCP/IP Processor (Transmission Control Protocol/Internet Protocol) and Flash ROM/RAM (Read Only Memory/Random Access Memory) that enable the fixed-phone/ground telephone network end-user to directly access the websites that provide e-Services via IVR and Internet applications.
      The SIM/Smart Card Reader design includes (as an optional feature) the electronic circuitry, logic, microcode, cables, accessories and connections (FIGS. 8 and 9) that are necessary to connect and operate a 2.5″ Paper-roll Thermal or Ink Printer, for the end-user convenience to print the payment receipts immediately upon completing the e-services/e-Payment transaction, whether when using IVR applications (FIGS. 1 and 4), or using Internet applications (FIGS. 2, 3 and 5).
      The SIM/Smart Card reader design include (as an optional feature) the electronic circuitry, logic, microcode, cables, accessories and connections (FIGS. 8 and 9) that are necessary to connect and operate a small LCD Display Screen, for the end-user convenience to review the data entered from the fixed-phone keypad, view and read the system issued messages and directions when using the IVR application to perform e-services/e-Payment transactions (FIGS. 1 and 4).
   In addition, the presented invention suggests the production of a new generation of fixed telephone line sets with integrated SIM/Smart Card Reader (FIG. 4 and FIG. 5). In this new generation of fixed telephone sets, the LCD display screen, the USB cable interface and the 2.5″ paper-roll printer ports become standard features.
(2) The e-Services (e-Government, e-Commerce) and e-Payment to be provided remotely through:
   The same central systems of Telecom Operators managing Mobile Phone Networks that utilize the SIM Cards in authenticating/authorizing remote end-users (as already exist in various e-Services/e-Payment applications serving the Mobile Platform), or
   The same central systems of Telecom Operators managing Fixed Phone Networks that use Intelligent Network applications, after performing the development and re-engineering activities to it that are necessary to make it accommodate the SIM based applications and tools required to manage the authentication/authorization processes that control the end-users access to the e-Services/e-Payment applications via landline networks.
(3) The introduced invention collectively avails all the benefits and facilities of existing e-Payment tools and methods into one e-Payment Integrated Scheme that offers a seamless and scalable platform for the various levels of end-users to upgrade the tools they are using according to the level of their financial capabilities, where the e-Payment Integrated Scheme is characterized by the following:
   The e-Payment Integrated Scheme links and integrates the following various e-Payment tools, schemes and methods that currently exist in real life:
      Prepaid Cards
      Electronic Prepaid Accounts
      Credit/Normal Banking Cards
   Each e-Services/e-Payment subscriber will be assigned an electronic bank account, where the end-user will:
      Use of the same SIM Card in both Mobile Phones as well as Fixed-Line Phones SIM/Smart Cards Reader.
      Use the same Smart Card in both ATM machines as well as Fixed-Line Phones SIM/Smart Cards Reader.
      Access the e-Services/e-Payments via:
         Fixed-Phones (using the introduced SIM/Smart Cards Reader) in association with Internet applications. Or;
         Fixed-Phones (using the introduced SIM/Smart Cards Reader) in association with IVR applications without the need for any Personal Computers. In such a case, the end-user can perform the data entry either by using the keypad of the fixed-line telephone set, or will have the alternative option of using a Call Center Service (that will be availed as part of the presented e-Services/e-Payment scheme), where the Call Center agent will perform the data entry on behalf of the end-user. Or;

'Mobile Phones and Wireless Devices in association with IVR, Internet and WAP applications (as already exists in real life through various embodiment solutions that address the Mobile/Wireless Platform).
e-Services/e-Payment subscriber will be able to effect e-Payments through either one of the following alternatives:
   Using Credit Cards or Prepaid Cards to refill (deposit) money into the electronic bank account mentioned above and e-Payments are effected as deductions (debits) from this electronic bank account. Or;
   Using Credit Cards to directly remit e-Payments to a Provider (as is the case nowadays in IVR and Internet applications) with the extra value of enjoying the same level of authentication/authorization privileges, where electronic monetary remittances using Credit Cards will be conditioned by the prerequisite use of the SIMI Smart Card (provided that such a prerequisite conditioning is agreed upon and arranged with the Financial Institution that issued the Credit Card—such as Visa, Master Card, . . . etc).
The Prepaid Cards presented in this e-Payment Integrated Scheme are characterized by the following:
   Will be used in integration with the new SIM/Smart Cards to charge a central electronic bank account of the e-services subscriber in a fashion similar to what currently exists in the prepaid cards used with mobile phone subscribers.
   Will be issued in various and progressive money values, and will work as an e-Payment tool that aim to facilitate the e-Payment for the end-user categories who are not wealthy and consequently are unable to have credit cards or normal bank accounts.
   The above mentioned Prepaid Cards are suggested to be sold through various outlets (such as supermarkets, gas stations, post offices, . . . etc).
In addition, the presented invention suggests the development and production of a new “low-cost” mobile phone to be used only in remote electronic services to help in spreading the use of e-Services/e-Payments within low income individuals. Where:
   The SIM card issued for the e-Services SIM subscriber will be dedicated only to e-Services/e-Payment, no vice communication service are allowed (except emergency numbers, such as ambulance, fire brigade, police, . . . etc).
   The new mobile keypad buttons and selection menus will be modified/re-engineered to suit the e-services applications and functions.
   The e-Services/e-Payment subscriber (with the New SIM inserted in this new mobile phone) will be allowed only to access the e-Services via IVR and/or WAP applications.
   It is also suggested that other value-add services to be added to the newly suggested mobile phone, such as sending and receiving electronic messages/mails, performing e-banking transaction/service functions, . . . etc.
(4) The invented e-Services Scheme is suggested to avail to the end-user the following various alternatives for Printing the e-Payment Receipts:
   In all types of e-services applications (IVR, Internet and WAP), based on the end-user choice, the e-Payment Receipts can be printed centrally within the e-Services Provider and later delivered to the end-user address location via mail courier (might already exist in real life through some providers).
   In IVR and Internet e-Services applications, the end-user can print the e-Payment Receipt immediately upon completing the e-Payment transaction using a 2.5″ Paper-roll Thermal (or Ink) Printer connectable to the SIMJ Smart Card Reader (item 7 in FIGS. 1, 2, 3, 4 and 5).
   In IVR and Internet e-Services applications, based on the end-user choice the data of the e-Payment Receipt can be recorded on the e-Service Smart Card (normal size cards) and later printed using an Automatic Teller Machine (ATM) closer to the end-user location, given that the ATM is prepared to provide this Printing Service (newly suggested printing embodiment).
   In Internet e-Services applications, the end-user (in addition to the printing options mentioned above) can print the e-Payment Receipts using Personal Computer standard printer facilities (already exists in real life in all Internet applications).
   In WAP e-services applications, the end-user can record the e-Payment Receipts data onto the e-services SIM Card storage (or the handheld device memory) and later transfers the e-Payment Receipts data to a Personal Computer via available link facilities (such as USB cable interface) and prints the recorded e-Payment Receipts using the Personal Computer standard printer facilities (might already exist in real life, where some providers send back undeniable electronic receipts to end-users).
   Also, in WAP e-Services applications, the end-user can record the data of the e-Payment Receipts on the e-Services SIM Card storage (or the handheld device memory) and later prints the e-Payment Receipts data using an ATM machine closer to the end-user location by transferring the recorded e-Payment Receipts data to the ATM machine via Infrared linkage facilities, and then prints the e-Payment Receipts using the ATM machine printer, given that the ATM is equipped with Infrared linkage feature and is prepared to provide this printing service (newly suggested printing embodiment).

### BRIEF DESCRIPTION OF DRAWINGS

FIG. (1): Demonstrates the connections of the fixed line telephone set and the external SIM/Smart card reader device.

Item (1) Fixed line telephone outlet.

Item (2) The external SIM/Smart card reader device.

Item (3) Parallel telephone line port, for connecting desktop personal computers (data port).

Item (4) Telephone line input port.

Item (5) The new e-Services normal size Smart card.

Item (6) The new e-Services SIM card.

Item (7) 2.5″ Paper-roll Thermal (or Ink) Printer.

FIG. (2): Demonstrates the connections of a desktop personal computer, fixed line telephone set and external SIM/Smart card reader device.

Item (1) Fixed line telephone outlet.

Item (2) The external SIM/Smart card reader device.

Item (3) Parallel telephone line port, for connecting desktop personal computers (data port), connected to a desktop Personal Computer.

Item (4) Telephone line input port.

Item (5) The new e-Services normal size Smart card.

Item (6) The new e-Services SIM card.

Item (7) 2.5″ Paper-roll Thermal (or Ink) Printer.

Item (8) Enlarged picture of the new e-Services normal size Smart card.

Item (9) Enlarged picture of the new e-Services SIM card.

FIG. (3): Demonstrates a desktop personal computer connected to a fixed line network via fax/modem card and the external card reader device.

Item (1) Fixed line telephone outlet.

Item (2) The external SIM/Smart card reader device.

Item (3) Fixed telephone line connected directly to a desktop Personal Computer via fax/modem card.

Item (4) Fixed telephone line connected to the ground network.

Item (5) The new e-Services normal size Smart card.

Item (6) The new e-Services SIM card.

Item (7) 2.5″ Paper-roll Thermal (or Ink) Printer.

Item (8) Enlarged picture of the new e-Services normal size Smart card.

Item (9) Enlarged picture of the new e-Services SIM card.

FIG. (4): Demonstrates the connection of a fixed line telephone set with internally integrated SIM/Smart card reader device.

Item (1) Fixed line telephone outlet.

Item (2) A new fixed line telephone set with a SIM/Smart card reader integrated inside.

Item (3) Parallel telephone line port, for connecting desktop personal computers (data port).

Item (4) Telephone line input port.

Item (5) The new e-Services SIM/Smart card.

Item (6) Input/Output port for connecting the 2.5″ Paper-roll Thermal (or Ink) Printer.

Item (7) 2.5″ Paper-roll Thermal (or Ink) Printer.

Item (8) Enlarged picture of the new e-Services SIM card.

Item (9) Enlarged picture of the new e-Services normal size Smart card

FIG. (5): Demonstrates a desktop Personal Computer connected to a fixed line telephone set with the new SIM/Smart card reader integrated inside.

Item (1) Fixed line telephone outlet.

Item (2) A new fixed line telephone set with a SIM/Smart card reader integrated inside.

Item (3) Parallel telephone line port, for connecting desktop personal computers (data port), connected to a desktop Personal Computer.

Item (4) Telephone line input port.

Item (5) The new e-Services SIM/Smart card.

Item (6) Input/Output port for connecting the 2.5″ Paper-roll Thermal (or Ink) Printer.

Item (7) 2.5″ Paper-roll Thermal (or Ink) Printer.

Item (8) Enlarged picture of the new e-Services SIM card.

Item (9) Enlarged picture of the new e-Services normal size Smart card

FIG. (6): Demonstrates the access of e-Services via cellular network using various mobile devices (portable Personal Computer connected to a mobile phone, handheld communicator device, PDA . . . etc).

Item (1) Mobile phone device.

Item (2) Special cable to connect mobile phones to portable Personal Computers.

Item (3) Portable personal computer.

Item (4) PDA (Personal Digital Assistant) device.

Item (5) Handheld communicator device.

FIG. (7): Demonstrates a general schematic diagram of the various access alternatives to the central e-Services provider.

Item (1) The equipment and infrastructure systems and applications installed within the inside plant of the Telecom Operator assigned the responsibility of the e-Services access provision.

Item (2) The equipment and infrastructure systems and applications installed within the inside plant of the fixed line network telephone operator.

Item (3) Equipment and infrastructure systems and applications of a mobile operator rather than the one providing the e-Services.

Item (4) Mobile phone communicates with the e-Services Telecom Operator, through another mobile operator.

Item (5) Portable Personal Computer communicates via a mobile phone with the e-Services Telecom Operator through another mobile operator.

Item (6) Fixed line telephone set with the new SIM/Smart card reader integrated inside and communicates with the e-Services Telecom Operator through a Fixed-Line Network Telecom Operator.

Item (7) Desktop personal computer connected to the ground line network and equipped with the new SIM/Smart card reader.

Item (8) Portable Personal Computer communicates directly with the e-Services Telecom Operator via a mobile phone.

Item (9) The newly suggested e-Services mobile phone that supports only e-Services and remote payments, communicates with the Telecom Operator providing the e-Services.

FIG. (8): Demonstrates a schematic diagram for the internal components of the new SIM/Smart card reader device (internal or external).

Item (1) Power supply circuits with matching impedance equivalent to the fixed telephone line impedance, the power supply circuits generate from the voltage of the fixed line the voltages needed to operate the SIM/Smart card reader circuits and components.

Item (2) Logic and control circuits.

Item (3) Voltage bus.

Item (4) The new SIM card.

Item (5) SIM reader cartridge.

Item (6) Controlled bus circuitry with a matching impedance equivalent to the fixed line impedance.

Item (7) Three-way gating control circuit with a matching impedance equivalent to the telephone line impedance.

Item (8) MODEM, communication and logic circuits to code/decode the logical addresses, instructions and tones with appropriate matching impedance equivalent to the fixed line circuitry.

Item (9) The fixed telephone line connected to the ground network, and connected in parallel to the new SIM/Smart card reader.

Item (10) TCP/IP Processor to enable the end-user to directly communicate with Internet websites that provide the e-Services and handle the e-Services IVR and Internet applications.

Item (11) Flash ROM/RAM.

Item (12) 2.5′ Paper-roll Thermal (and Ink) printer logic circuits and adapter (similarly logic circuits and adapter exist to operate and handle the Small LCD Display Screen).

Item (13) Input/Output port to connect the 2.5′ Paper-roll Thermal (or Ink) printer (similarly an Input/Output port exist connect the Small LCD Display Screen).

Item (14) Enlarged picture of the new e-Services normal size Smart card.

Item (15) Enlarged picture of the new e-Services SIM card.

Item (16) Normal size Smart card entry slot.

FIG. (9): Demonstrates a 3D schematic of the new SIM/Smart card reader device (external model).

Item (1) External casing of the SIM/Smart card reader device (external model), and the figure item demonstrates the small size of the external device (around 8×10×2.5 cm).

Item (2) Ground telephone line input port (RJ type connector).

Item (3) Ground telephone line output port (RJ type connector).

Item (4) Input/Output port to connect the 2.5′ Paper-roll Thermal (or Ink) printer.

Item (5) Output port to connect the Small LCD Display Screen.

Item (6) Picture of the new e-Services SIM card.

Item (7) Picture of the new e-Services normal size Smart card.

Item (8) USB port to connect SIM/Smart card reader device to Personal Computers via USB cable.

### BEST MODE FOR CARRYING OUT THE INVENTION

Remote access to e-Services (e-Government, e-Commerce) and e-Payment will be provided through the same central systems and applications installed within the inside plant infrastructure of Mobile Operators, that are based on the SIM technology, tools and functions after doing the necessary development and re-engineering activities to it to make it suitable for handling the e-Services remote access control, authentication, protection and functionalities (also for the objective of presented invention the central systems that will be re-engineered/developed to manage and control the e-Services/e-Payment applications, can be the inside plant Intelligent Network Systems of Fixed-Lines Telecom Operators that are normally used to manage the fixed phone subscribers' services).

Such central systems, development, re-engineering, administration and management shall be handled and sponsored by a locally capable Telecom Operator having the appropriate technical and financial capacities needed to support the remote e-Services on a country level and in coordination with a privileged organization that is trusted on the country level (in Egypt it is suggested that such coordination is done between Telecom Egypt and the Civil Status Organization of the Ministry of Interiors responsible for managing the national ID's of all citizens on the country level).

Both organizations (capable telecom operator and trusted organization) coordinate and liaise with local and international financial organizations (banks in addition to financial services institutions such as: Visa, Master Card, American Express . . . etc) to cater for the handling and management requirements of the central electronic banking accounts and the remote e-Payment transaction processing.

The above mentioned consortium (capable telecom operator, trusted organization, local and international financial organizations) will be the country e-Services/e-Payment custodian and will issue a SIM and a normal size Smart cards for each citizen requires to subscribe in the e-Services.

The e-Services will be provided through IVR (Interactive Voice Response) applications through fixed line telephones using the ground network communications as well as mobile phones using the cellular network communications.

The e-Services will be also provided via WAP (Wireless Application Protocol) and Internet applications.

The e-Services subscriber SIM or normal size Smart Cards will contain all the data required to handle a complete Public Key/Private Key Infrastructure scheme necessary to manage the e-Services subscriber profile and privileges plus managing and handling the subscriber e-Payment transactions through an electronic central banking account that is opened for each e-Services subscriber. In addition, the same SIM and/or normal size Smart Cards may carry data of other services (such as mobile phone and/or banking/credit card), according to the subscriber needs and request.

The above mentioned e-Services consortium will coordinate the issuance of Prepaid Cards with different and progressive monetary values, these Prepaid Cards will be used to charge the respective prepaid card money value into the central electronic bank account of the e-Services subscriber and the remote e-Payments will be effected as deductions form the electronic bank account.

Also, e-Payments can be effected using normal banking/credit cards in association with the authentication/access controls and functionalities provided by the new SIM/Smart cards infrastructure and scheme.

The e-Services provider is to allocate specific telephone codes and telephone numbers for the various categories of the e-Services (e-Government and e-Commerce), for example 088-888 8888 for e-Government services and 099-999 9999 for e-Commerce services.

Accessing the e-Services via such numbers necessitate the physical use of the new SIM/Smart Cards inserted in the newly invented SIM/Smart Cards Reader with fixed line phones, or the Smart SIM card inserted inside the mobile phone or handheld devices as is already exists in real life.

### INDUSTRIAL APPLICABILITY

To exploit the invention there are eight components that have to be developed, re-engineered and/or manufactured.

The first component is the Telecom Operator central systems and applications, where the developments and re-engineering activities have to be coordinated between the whole e-Services consortium parties (telecom company, trusted organization, local and international financial institutions). The development and re-engineering of the various components are already proven technologies that are used with different credit/banking cards applications used in association with ATM and/or POS machines, SIM based mobile phones and handheld device service applications, including the targeted e-Services/e-Payment applications.

The second component is the new SIM/Smart Cards design and manufacturing, where it is also a proven technology used in various mobile, banking, credit and prepaid cards that are based on the smart chip technologies.

In the proposed invention scheme, the exploitation necessitates that the parties members of the e-Services consortium (telecom company, trusted organization, local and international financial institutions) coordinate together the technical and legislative components needed to specify the tools, functionalities, protocols and procedures associating the electronic use of the new SIM/Smart cards with fixed line and mobile telephone sets and devices. In the presented scheme each subscriber will be granted two versions of the e-Services/e-Payment cards, namely; an e-Services SIM (which is—as already exists in real life—a modified smart version of the SIM cards normally used in mobile phones) and an e-Services Smart Card (which is a modified smart version of the cards normally used in the Point Of Sale “POS” and Automatic Teller Machines “ATMs”). The e-Services subscriber will be able to interchangeably use both card versions, however the e-Services central systems will allow the subscriber to use one e-Services card at a time.

The third component is the newly invented SIM/Smart Cards Reader to be used in association with fixed line telephone devices, where the proposed technology is proved in various applications that involve add-on of devices to the normal fixed line telephones, such as caller-ID devices, long distance call controller devices, fixed line SMS devices, . . . etc.

The design and manufacturing of the newly invented SIM/Smart Cards Reader will require the design and manufacturing of electronic circuits; electromechanical components; VLSI circuits including microprocessors and microcode technology items (TCP/IP processor, flash ROM/RAM memory); circuitry; connectivity components and accessories required to connect the invented SIM/Smart Cards Reader to: Fixed-Line Network/Fixed-Line Handsets, Thermal/Ink Printers and LCD display screen.

The SIM/Smart Cards Reader functionality and logic designs will considerably depend on BIOS (Basic Input Output System) and Micro Codes so that the SIM/Smart Cards Reader can be updated and upgraded through the use of specialized PC (Personal Computer) programs. Accordingly, the SIM/Smart Card Reader will be equipped with USB port and interface to enable its linkage with Personal Computers.

The SIM/Smart Cards Reader will also require casing that has to satisfy the safety requirements of customer use and as well has to have a customer appreciated cosmetic appearance, such casing will require artwork design, mechanical dies and moulding machinery for mass production.

The fourth component is the Central Electronic Bank accounts and Prepaid Cards, where also such a technology is proven and used in the normal mobile phone voice services for subscribers using the prepaid cards scheme, and also are proven in some Mobile e-Services/e-Payment setups. In the introduced e-Services Scheme, the Telecom Operator will hold an electronic registry of the customer profile and the e-Services subscriber will use the Prepaid Cards to deposit money into his/her central account. The e-Payments will be deducted from the subscriber electronic account.

Also, the presented scheme introduces new service features that will be added to the use of Credit Cards (such as Visa, Masters, . . . etc), where the end-user will be able to directly remit e-Payments to a Provider (as is the case nowadays in IVR and Internet applications) with the extra value of enjoying the same level of authentication/authorization privileges, where electronic monetary remittances using Credit Cards will be conditioned by the prerequisite use of the SIM/Smart Card. Where, the prerequisite condition of using the e-Services SIM or Smart Cards to authenticate the end-user will be agreed upon and arranged with the Financial Institution that issued the Credit Card—such as Visa, Master Card, . . . etc.

The fifth component is the use of normal Fixed-Line Phones as access devices to the e-Services using both versions of the e-Service Cards (the SIM and the Smart Cards mentioned above) in association with the newly suggested SIM/Smart Cards Reader, where such technology is already proven in the Wireless (GSM and GPRS) “e-Services/e-Payment” services in association with Mobile and/or Handheld Devices.

The sixth component is the new generation of fixed line telephone sets with the invented SIM/Smart Card Reader integrated inside. In this new generation of telephone sets, the LCD display screen, the USB cable interface and the 2.5″ paper-roll printer ports become standard features.

The seventh component is the mobile phone dedicated only to the e-Services, where the new phone menus and keypad buttons are re-engineered and designed to optimally serve the e-Service transactions. The design and manufacturing of such a mobile telephone device will be similar to the normal mobile phones. However, the SIM card and the subscriber profile within the central systems of the e-Services provider will define the functionalities and privileges given to the subscriber and will limit it to the e-Service applications. The new mobile phone will allow the use of IVR, WAP and/or Internet applications to access and handle the e-Services and e-Payment transactions.

The eighth component is that availing and enabling the printing services of the e-Payment Receipts via Automatic Teller Machines (ATM) will require development and re-engineering activities to make the ATM prepared to perform the printing services.

The printing of the e-Payment Receipts recorded on the normal size Smart Cards will require re-engineering of the ATM programming.

The printing of the e-Payment Receipts recorded on the SIM Cards or memory of mobile or handheld devices, will require ATM hardware upgrade/re-engineering to enable the ATM of communicating with the mobile phones and handheld devices via Wireless (Infrared or Bluetooth) Linkage, in addition will also require re-engineering of the ATM programming.

1) The first claimed item is that the presented invention introduces One e-Services/e-Payment Orchestrated Scheme that is characterized by the following:
(a) It integrates, links and combines in one orchestrated scheme the following e-Services and e-Payment embodiments, tools and techniques that are currently available and that may be introduced in future:
The various shapes of Smart Cards that are used as authentication and authorization embodiments (physical tokens) that are used to protect e-Services and e-Payment transactions (Smart SIM Cards that are modified smart version of the SIM cards currently used in mobile phones and normal size Smart Cards that are modified smart version of the cards normally used in Automatic Teller Machines “ATMs”).
The various embodiments and physical apparatus/terminals (Fixed-Phones, Personal Computers, Mobile Phones, Wireless Devices, . . . etc) that are used to access e-Services and e-Payment applications and process their respective transactions.
The various e-Payment tools and techniques that enable the end-user (consumer) of electronically effecting the payments of received services or goods (such as Credit Cards, Prepaid Cards, Prepaid Electronic Accounts, . . . etc).
Provisioning of Printed Payment Receipts through various alternatives (end-user local printing facilities, the newly introduced ATM machines printing services and/or e-Services Provider Printing Facilities and delivering printed receipts to end-user via mailing courier).
(b) The values that are gained out of linking and integrating various tools and technology solutions into one orchestrated scheme, can be summarized in the following bullets:
The introduced scheme (through the use of SIM Cards “mentioned in claimed item #2 below” and the new Card Reader tool “as mentioned in claimed item #3 below”), extends the use of the e-Services/e-Payment solutions (which realize a good level of authentication/authorization controls and avail convenient e-Payment tools), that are currently available on the Mobile Devices platform to the Fixed Phones platform (either through IVR applications using Fixed-Phones “without the need for any Personal Computers” and Internet applications using Personal Computers connected to the Fixed-Line Networks). It is worth mentioning that the end-users will be able to interchangeably use the very same SIM Card between the both Mobile and Fixed Phone platforms.
The introduced scheme (through the use of Smart Cards “as mentioned in claimed item #2 below” and the new Card Reader tool “as mentioned in claimed item #3 below”), extends the use of the e-Services/e-Payment solutions (which realize a good level of authentication/authorization controls and avail convenient e-Payment tools), that are currently available on ATM (Automatic Teller Machines “except the physical withdrawal of cash”) to the Fixed Phones platform (either through IVR applications using Fixed-Phones “without the need for any Personal Computers” and Internet applications using Personal Computers connected to the Fixed-Line Networks). It is worth mentioning that the end-users will be able to interchangeably use the very same Smart Card between both ATM and Fixed Phone platforms.
The introduced scheme helps in closing the “Digital Divide” by enabling the poor and lowly educated personnel round the whole world (and specially within the developing countries) of easily and confidently using the e-Services and effecting e-Payments remotely, via IVR (Interactive Voice Response) applications using Fixed-Line Telephone Sets, where:
The end-users will be able to interact with the e-Services transactions via IVR without the need for any Personal Computers, while enjoying the values of authentication/authorization controls, through the use of the novel idea of having handy “Card Reader” tool (mentioned in the claim item #3 below) that is easily connectable to fixed-line telephone sets via normal RJ type connectors (FIGS. 1, 2 & 3 and FIG. 9 items 2 & 3).
The end-user will be able to perform the data entry either by using:
The keypad of the fixed-line telephone set, or
Using a Call Center Service (that will be availed as part of the presented e-Services/e-Payment scheme), where the Call Center agent will perform the data entry on behalf of the end-user.
The end-users will be able to effect e-Payments via Prepaid Cards/Electronic Banking scheme without the need of having credit cards.
The introduced scheme also introduces values and convenience to the end-users who are rich, professional and are highly educated, who prefer to use Internet/Desktop Personal Computers and Credit Cards in a secured environment, where:
The introduced scheme avails the same values of authentication/authorization controls via the Internet applications/Desktop Personal Computers, through easily connecting the same “Card Reader” tool (mentioned in the claim item #3 mentioned below) to the Personal Computer and the Fixed-Line Telephone Network, in which case no customizations nor installations of software (neither programs nor drivers) are needed on the end-user Personal Computer side.
In addition, the scheme introduces new service features that can be added to the use of Credit Cards (such as Visa, Masters, . . . etc), where the end-user will be able to directly remit e-Payments to a Provider (as is the case nowadays in IVR and Internet applications) with the extra value of enjoying the same level of authentication/authorization privileges, where electronic monetary remittances using Credit Cards will be conditioned by the prerequisite use of the SIM/Smart Card (provided that such a prerequisite conditioning is agreed upon and arranged with the Financial Institution that issued the Credit Card—such as Visa, Master Card, . . . etc).
The provisioning of Printed Payment Receipts through various alternatives (end-user local printing facilities, e-Services Provider Printing Facilities and delivering Printed Receipts to end-user via mailing courier and/or the newly introduced idea of ATM machines Printing Services “mentioned in claimed item #7 below”).

2) The second claimed item is that the presented scheme introduces “e-Services/e-Payment” SIM/Smart Cards that are used as a physical token for authentication/authorization functionalities that are currently in place, the introduced “e-Services/e-Payment” SIM/Smart Cards are characterized by:
(a) Two versions of the e-Services Smart Card are issued for each e-Services subscriber, the thing that is aimed to facilitate to the end-users the interchangeability and compatibility of the used e-Services/e-Payment access tools between various platforms (Mobile Phones, Fixed Phones and ATMI POS machines). The two versions of the e-Services Smart Card namely are:
Version #1, a new e-Services SIM Card (which is—as already exists in real life—a modified smart version of the SIM cards currently used in mobile phones), where the e-Services end-user can use this new SIM card to perform the following:
The traditional mobile phone services.
Acquire e-Services from e-Service Providers and perform the respective e-Service and e-Payment transactions through the e-Services applications and authentication/authorization processes, similar to what is currently available for Mobile Phones/Wireless Devices.
In addition the end-user can use the very same SIM Card in association with the Fixed-Line Phones through the use of the new SIM/Smart Cards Reader described in the claim item #3 mentioned below, where the end-user will be able to acquire e-Services from e-Service Providers and perform the respective e-Service transactions through the e-Services IVR applications (without the need for Personal Computers), or through the Internet applications (using Personal Computers), in association with the authentication/authorization processes in place.
Version #2, is a new e-Services Smart Card (which is a modified smart version of the cards normally used in the Point Of Sale “POS” and Automatic Teller Machines “ATMs”), where the e-Services end-user can use this new Smart Card to perform the following:
The traditional Point Of Sale “POS” and Automatic Teller Machines “ATMs” services.
In addition the end-user will be able to use the same Smart Card in association with the novel idea of the SIM/Smart Cards Reader (described in the claim item #3 mentioned below), where the end-user will be able to acquire e-Services from e-Service Providers and perform the respective e-Service and e-Payment transactions via Fixed-Line Phones through IVR applications (without the need for Personal Computers), or through Internet applications (using Personal Computers connected to Fixed-Line Phones), while enjoying the values of the authentication/authorization processes in place via the very same e-Services applications and authentication/authorization processes currently available for Mobile Phones/Wireless Devices (and/or the POS/ATM machines “except the physical withdrawal of cash service”).
(b) Both SIM and Smart Card versions will contain all data required to handle their interchangeable use (one card version to be in use at a time, . . . etc) and as well shall contain all the conventional data required for managing a complete Public Key/Private Key Infrastructure, as per the schemes and methodologies currently in place and that are necessary to manage the authentication of the e-Services subscriber and manage his/her profile and privileges plus managing the security of the performed e-Services and e-Payment transactions.
(c) In both SIM and Smart Card versions, the end-user authentication/authorization processes will oblige the end-user to pass the following three tiers of security control:
The first is the physical use of the new SIM/Smart cards as a mandatory tool to access the e-Services remote systems;
The second is the exact data entry of the end-user ID (such as the citizen national number); and
The third is the correct data entry of the end-user PIN code.
(d) The SIM Card version will be used by the end-user (interchangeably between Landline Handsets, Mobile Phones) as physical tokens to interact with and activate the authentication/authorization processes and functionalities.
(e) The Smart Card version will be used by the end-user (interchangeably between Landline Handsets, Desktop Personal Computers and “POS”/“ATM” machines) as physical tokens to interact with and activate the authentication/authorization processes and functionalities.

3) The third claimed item is that the design of the presented Orchestrated Scheme is distinguished by introducing a new SIM/Smart Cards Reader (FIGS. 8 and 9) that is used in association with the Fixed-Line Phones, where the new SIM/Smart Cards Reader is characterized by the following:
(a) It is easily connectable to fixed line telephone sets and fixed line network via normal RJ type connectivity (FIG. 9 items 2 and 3).
(b) The advanced internal design of the presented reader, contains TCP/IP Processor, Flash ROM/RAM, . . . etc, which introduce higher intelligences that facilitate the following:
Produces more convenience regarding the performance of the re-engineering and development activities that are required to be done to the e-Services/e-Payment central systems to accommodate e-Commerce and e-Government service provider websites into the overall Orchestrated e-Services/e-Payment Scheme.
Allows the end-user of communicating with the Internet via the various types of landline communications modes that are available without the need for any customizations or adjustments, whether the communication mode is dial-up, ISDN or ADSL.
Enables the end-user of using the Fixed-Line Phones to directly access the websites of the e-Service providers, where the end-user will be able to fully perform the transactions of e-Services/e-Payments via either of the following application means:
IVR applications without the need for any Personal Computers.
Internet applications using Desktop Personal Computers.
(c) The advanced internal design of the presented reader, contains Three-Way Gating Control circuits with a Matching Impedance equivalent to the telephone line impedance, where such design permits more flexibility in the communications process and enables easier management of the data interchanged between the end-user and the central e-Services/e-Payment provider system in a synchronized and/or intermixed modes, and thus allows the end-user through dialing one number of an e-Services central system to seamlessly perform e-Services and e-Payments transactions via either IVR applications without the need for any computers, or via Internet applications using a Desktop PC connected to the landline network.
(d) The electromagnetic/electromechanical design of the presented reader enables it of reading and interacting with:
The new e-Services SIM Cards (a modified smart version of the SIM cards currently used in mobile phones as mentioned above).
The new e-Services Smart Cards (a modified smart version of the cards normally used in Point Of Sale “POS” and Automatic Teller Machines “ATM” as mentioned above).
(e) The presented reader design (electronic circuitry, logic, microcode, cables, accessories and connections) enables it of interfacing and operating the following optional devices:
Thermal or Ink (2.5″ Paper-roll) Printer, for the end-user convenience to print the payment receipts immediately upon completing the e-Services/e-Payment transaction, whether when using IVR applications.
Small LCD Display Screen, for the end-user convenience to review the data entered from the fixed-phone keypad, view and read the system issued messages and directions when using the IVR application to perform e-Services/e-Payment transactions.

4) The fourth claimed item is producing a New Generation of Fixed Telephone Sets with the same innovated SIM/normal size Smart Cards Reader integrated inside (item 2 in FIG. 4 and FIG. 5), for easier and more convenient use of the new SIM/Smart cards in conjunction with fixed telephone sets. The integrated SIM/Smart Cards Reader will have all the components and features available in the external one (FIG. 8 demonstrates a schematic diagram of the reader internal design). The small LCD Display Screen will be integrated within the telephone set display screen as a standard feature. In addition, the interface port for connecting and operating a 2.5″ Paper-roll Printer (Thermal or Ink) will become also standard features.

5) The fifth claimed item is that the presented invention suggests the development and production of a new “Low-Cost” Mobile Phone to be used only in remote electronic services to help in spreading the use of e-Services/e-Payments within low income individuals, where:
(a) The SIM card issued for the e-Services SIM subscriber will be dedicated only to e-Services/e-Payment, no vice communication service are allowed (except emergency numbers, such as ambulance, fire brigade, police, . . . etc).
(b) The new mobile keypad buttons and selection menus will be modified/re-engineered to suit the e-services applications and functions.
(c) The e-Services/e-Payment subscriber (with the New SIM inserted in this new mobile phone) will be allowed only to access the e-Services via IVR and/or WAP applications.
(d) It is also suggested that other value-add services to be added to the newly suggested mobile phone, such as sending and receiving electronic messages/mails, performing e-banking transaction/service functions, . . . etc.

6) The sixth claimed item is that the presented Scheme collectively avails all the benefits and facilities of existing e-Payment tools and methods into one Integrated e-Payment Scheme that offers a seamless and scalable platform for the various levels of end-users to upgrade the tools they are using according to the level of their financial capabilities, where the Integrated e-Payment Scheme is characterized by the following:
(a) The e-Payment Integrated Scheme links the available tools and embodiments of e-Payment into one e-Payment Integrated Scheme, where the presented e-Payment Scheme integrates the following various e-Payment tools, schemes and methods that currently exist in real life:
Prepaid Cards
Electronic Prepaid Accounts
Credit/Normal Banking Cards
(b) The presented Integrated e-Payment Scheme combines the use of the various e-Payment tools with the physical use of the e-Services SIM/Smart Cards that are referred to in the claim item #2 mentioned above, to ensure realization of proper e-Services/e-Payment transactions protection through the use of the authentication/authorization methods that are currently available.

7) The seventh claimed item is that the presented Scheme Design is distinguished by the new ideas proposed for Printing the e-Payment Receipts using ATM machines (in addition to the other alternative facilities that currently exist for Printing the e-Payment Receipts), where the e-Payment Receipt data can be recorded on e-Services Card (SIM or normal size Smart Cards) and later the end-user can print the recorded e-Payment Receipts using an ATM machine that is equipped to provide the service of printing e-Payment Receipts as already described under the section titled “Disclosure of the Invention” above.
